(19) United States
(12) Patent Application Publication
(10) Pub. No.: US 2016/0118229 A1
(43) Pub. Date: Apr. 28, 2016

(54) PLASMA PROCESSING APPARATUS

(71) Applicant: PANASONIC INTELLECTUAL PROPERTY MANAGEMENT CO., LTD., Osaka (JP)

(72) Inventors: Tetsuhiro IWAI, Osaka (JP); Shogo OKITA, Hyogo (JP)

(21) Appl. No.: 14/865,398

(22) Filed: Sep. 25, 2015

(30) Foreign Application Priority Data
Oct. 22, 2014 (JP) 2014-215146

(51) Int. Cl. H01J 37/32

(52) U.S. Cl. CPC H01J 37/32532; H01J 37/32458; H01J 37/321; H01J 37/32091

(57) ABSTRACT

A plasma processing apparatus includes: a vessel which includes a reaction chamber, atmosphere within the reaction chamber capable of being depressurized; a lower electrode which supports an object to be processed within the reaction chamber; a dielectric member which includes a first surface and a second surface opposite to the first surface, and which closes an opening of the vessel such that the first surface opposes an outside of the reaction chamber and the second surface opposes the object to be processed; and a coil which opposes the first surface of the dielectric member, and which generates plasma within the reaction chamber. The dielectric member has a groove formed in the first surface of the dielectric member, and at least a part of the coil is disposed in the groove.

### CROSS-REFERENCES TO RELATED APPLICATION(S)

This application is based on and claims priority from Japanese Patent Application No. 2014-215146 filed on Oct. 22, 2014, the entire contents of which are incorporated herein by reference.

### BACKGROUND

1. Field of the Invention

One or more embodiments of the present invention relate to a plasma processing apparatus of an inductively coupled plasma type.

2. Description of Related Art

In one example of a plasma processing apparatus of an inductively coupled plasma (ICP) type, a top portion of a reaction chamber is hermetically sealed by a plate-shaped dielectric member, and a coil for supplying radio frequency power is disposed on the reaction chamber. As atmosphere within the reaction chamber is depressurized, the dielectric member is required to have a thickness ensuring sufficient mechanical strength for supporting the atmospheric pressure. However, the thicker the dielectric member is, the larger a loss of radio frequency power supplied to plasma from the coil becomes.

In view of this, JP-A-2008-306042 proposes to support a lower surface side of the dielectric member by a beam-like structure. According to this proposal, the sufficient mechanical strength can be ensured even in a case of thinning the dielectric member.

However, as irregular portions (protruding and recess portions) are formed on the lower surface side of the dielectric member due to the beam-like structure, structure of the top portion of the reaction chamber becomes complicated and hence labor of maintenance of the apparatus increases. Further, the irregular portions due to the beam-like structure may badly influence on plasma distribution.

### SUMMARY

An object of one or more embodiments of the invention is to provide a plasma processing apparatus which is small in a loss of radio frequency power supplied to plasma from a coil, simple in structure and excellent in maintainability.

One or more embodiments of the invention provides a plasma processing apparatus, including: a vessel which includes a reaction chamber, atmosphere within the reaction chamber capable of being depressurized; a lower electrode which supports an object to be processed within the reaction chamber; a dielectric member which includes a first surface and a second surface opposite to the first surface, and which closes an opening of the vessel such that the first surface opposes an outside of the reaction chamber and the second surface opposes the object to be processed; and a coil which opposes the first surface of the dielectric member, and which generates plasma within the reaction chamber, wherein the dielectric member has a groove formed in the first surface of the dielectric member, and wherein at least a part of the coil is disposed in the groove.

In the plasma processing apparatus according to one or more embodiments of the invention, as at least a part of the coil is disposed within the groove formed in the first surface of the dielectric member, a loss of radio frequency power supplied to the plasma from the coil becomes small. Further, as the second surface of the dielectric member can be formed as a flat surface having no irregularity, maintenance becomes easy and plasma distribution is improved.

### BRIEF DESCRIPTION OF THE DRAWINGS

FIG. 1 is a sectional view schematically showing structure of a plasma processing apparatus according to a first embodiment of the invention;

FIG. 2A is a longitudinal sectional view schematically showing an arrangement of a dielectric member and a coil according to the first embodiment, and FIG. 2B is a plan view of the dielectric member;

FIG. 3A is a longitudinal sectional view schematically showing structure of the dielectric member and electrode patterns according to the first embodiment, and FIG. 3B is a longitudinal sectional view obtained by enlarging a size of the structure of FIG. 3A in a vertical direction;

FIG. 4 is a plan view of a first electrode pattern (electric heater) according to the first embodiment;

FIG. 5 is a plan view of a second electrode pattern (plate electrode) according to the first embodiment;

FIG. 6A is a longitudinal sectional view schematically showing an arrangement of a dielectric member and a coil according to a second embodiment of the invention, and FIG. 6B is a plan view of the dielectric member; and

FIG. 7A is a longitudinal sectional view schematically showing an arrangement of a dielectric member and a coil according to a third embodiment of the invention, and FIG. 7B is a plan view of the dielectric member.

### DETAILED DESCRIPTION

### First Embodiment

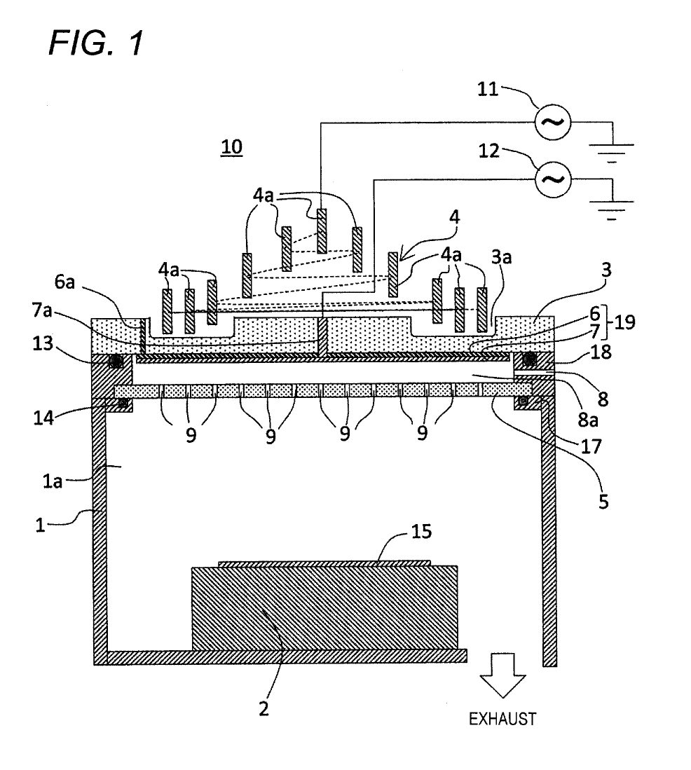

FIG. 1 shows a configuration of a dry etching apparatus 10 of an inductively coupled plasma (ICP) type, which is an example of a plasma processing apparatus according to a first embodiment of the invention. The dry etching apparatus 10 includes a vessel 1 having a reaction chamber 1a the inner atmosphere of which can be depressurized, a lower electrode 2 for supporting a substrate 15 as an object to be processed within the reaction chamber 1a, a dielectric member 3 which closes an opening of the vessel 1 and faces the substrate 15 to be processed, and a coil 4 which is disposed on an outer side of the dielectric member 3 opposite to the reaction chamber 1a and generates plasma within the reaction chamber 1a. The dielectric member 3 has a first surface and a second surface opposite to the first surface, and the first surface opposes the coil 4 (i.e., the outside of the reaction chamber 1a) and the second surface opposes the substrate 15 (i.e., an inside of the reaction chamber 1a).

The vessel 1 has an almost cylindrical shape with an opened top portion. The opening of the top portion is hermetically sealed by the dielectric member 3 as a lid. Atmosphere within the reaction chamber 1a is exhausted by a predetermined pumping device (not shown) and maintained at a depressurized atmosphere. The vessel 1 is provided with a gate (not shown) for loading a substrate 15 into the vessel and unloading it therefrom. Bias voltage is applied to the lower electrode 2. The lower electrode 2 may have a function of electrostatically chucking and holding a substrate 15 and may be provided with a circulation passage of refrigerant.

The dielectric member 3 has an almost circular plate shape in conformance with the opening shape of the vessel 1. A groove 3a is formed in one surface of the dielectric member 3 outside the reaction chamber 1a (i.e., the first surface of the dielectric member 3) so as to make the dielectric member 3 partially thin. At least a part of the coil 4 is disposed within the groove 3a. Consequently, the part of the coil disposed within the groove 3a is made closer to the plasma, and hence a loss of radio frequency power can be suppressed. As the groove 3a is partially formed on the first surface of the plate-shaped dielectric member 3, a mechanical strength of the dielectric member 3 does not largely degrade.

A first holder 17 for supporting a cover 5 is supported by an upper end of a side wall of the vessel 1 in a manner that the cover 5 is supported on the first holder 17 via a second elastic ring 14. An outer periphery of the cover 5 is fixed by a second holder 18 for supporting the dielectric member 3. The dielectric member 3 is supported on the second holder 18 via a first elastic ring 13. The cover 5 protects a surface of the dielectric member 3 on the reaction chamber 1a side (i.e., the second surface of the dielectric member 3) from the plasma.

The second holder 18 is provided with a gas introduction port 8 for introducing material gas (process gas) of the plasma into the reaction chamber 1a from a predetermined gas supply source. The process gas stays within a fine gap 8a formed between the dielectric member 3 and the cover 5 and then is ejected into the reaction chamber 1a from a plurality of gas injection ports 9 provided at the cover 5. The plurality of gas injection ports 9 are preferably arranged, for example, in a concentric manner.

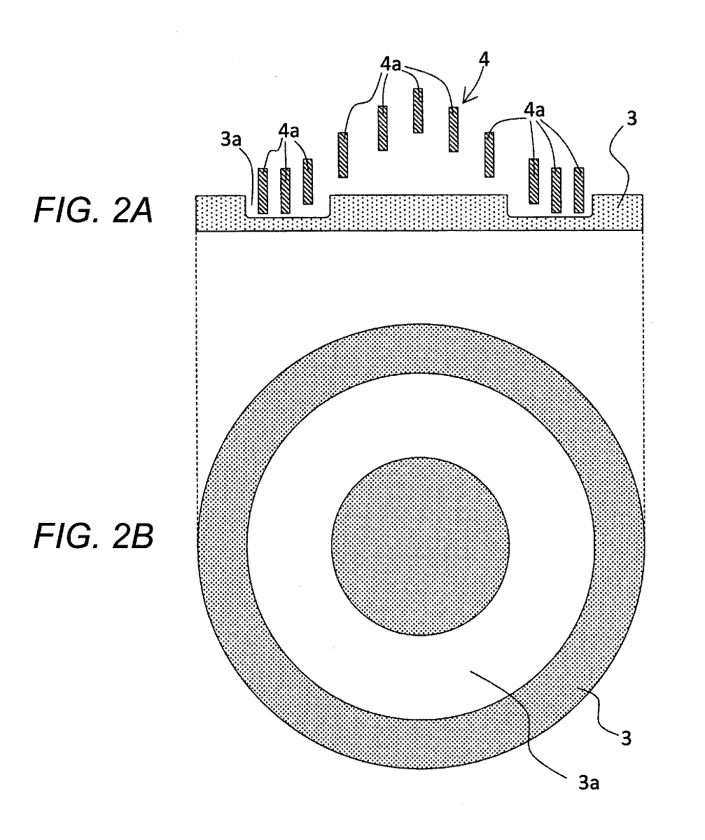

FIG. 2A schematically shows an arrangement of the dielectric member 3 and the coil 4 according to the embodiment. The coil 4 is formed by a conductor 4a extending spirally from the center of the coil toward an outer periphery thereof as viewed from a direction perpendicular to (the surface of) the dielectric member 3 (hereinafter also referred to as “in plan view”). The conductor 4a may be, for example, a metal plate of a ribbon-shape or a metal line. The number of the conductor 4a forming the coil 4 is not limited to a particular number and the shape of the coil 4 is also not limited to a particular shape. For example, the coil may be a single spiral type coil including the single conductor 4a or a multi spiral type coil including a plurality of the conductors 4a. Further, the coil may be a plane type coil which is formed by extending the conductor 4a spirally within the same plane in parallel to the surface of the dielectric member 3 or may be a stereoscopic type coil which is formed by changing the conductor in a vertical direction with respect to the surface of the dielectric member 3 while extending the conductor 4a spirally. The coil 4 is electrically connected to a first radio frequency power supply 11 via a matching circuit (not shown). In FIGS. 1 and 2, the coil 4 is formed in a manner that a distance between the dielectric member 3 and the coil 4 becomes larger at a portion near the center of the coil than a portion near the outer periphery of the coil. However, the positional relation between the coil 4 and the dielectric member 3 is not limited to this arrangement.

As shown in FIG. 2B, the groove 3a preferably has an annular shape which has a center substantially overlaps with a center of the coil 4 as viewed from a direction perpendicular to the surface of the dielectric member 3. According to this arrangement, the coil 4 can be easily disposed within the groove 3a. In this respect, this feature that the center of the annular groove 3a substantially overlaps with the center of the coil 4 may mean that the center of the groove coincides with the center of the coil, or may mean that each of these centers resides, for example, within a circle having a radius of 100 mm as the groove 3a and the coil 4 are viewed from a vertical direction with respect to the surface of the dielectric member 3.

A depth of the groove 3a is not limited to a particular size. Even if the groove 3a is shallow, effect of suppressing a loss of the radio frequency power can be obtained to some extent. In this respect, supposing that a thickness of the plate-shaped dielectric member 3 having a uniform thickness before forming the groove 3a is T, the groove 3a is preferably formed to have the maximum depth D in a range from 0.25 T to 0.45 T. From a viewpoint of ensuring strength, a ratio (100 s/S (%)) of an area s of the groove 3a formed in the first surface of the dielectric member 3 in plan view with respect to the entire area S of the first surface of the dielectric member in plan view is preferably set to be in a range from 2 to 50%.

The groove 3a may be formed by machining the dielectric member in such a manner of cutting the first surface of the plate-shaped member having a uniform thickness and having both flat surfaces.

Plasma (inductively coupled plasma) is generated in a region near the coil 4 at an upper part within the reaction chamber 1a, by flowing radio frequency current into the coil 4. A degree of inductive coupling between the coil 4 and the plasma can be increased by shortening a distance between the coil 4 and the reaction chamber 1a or increasing a winding density of the coil 4.

In order to obtain plasma with good uniformity at a surface of a substrate 15, it is preferable to generate, at the upper part within the reaction chamber 1a, plasma having a plasma density distribution (doughnut shaped distribution) higher at an outer peripheral portion than a portion near the center and to disperse the plasma over the surface of a substrate. Further, in order to form the plasma having the doughnut shaped distribution at the upper part within the reaction chamber 1a, a distance between the reaction chamber 1a and the coil 4 at the portion near the center may be set to be relatively large. Consequently, a coupling degree between the coil 4 and the plasma can be made low at the portion near the center. As a result, the center side portion of the coil 4 may not be disposed within the groove 3a. As shown in FIGS. 1 and 2, at least the coil portion corresponding to the center of the coil 4 may be disposed completely outside of the groove 3a.

In an outer peripheral side portion of the coil 4, as the coil 4 is disposed within the groove 3a, a distance between the reaction chamber 1a and the coil 4 is made short and hence the coupling degree between the coil 4 and the plasma can be made high. Where a length of the conductor 4a forming the coil 4 is L (from a first end on a center side to a second end on an outer peripheral side), and two regions of the conductor 4a is defined as a center side portion having a length 0.5 L from the first end of the coil 4 and a remaining outer peripheral side portion, a ratio of the center side portion disposed within the groove 3a is preferably set to be smaller than a ratio of the remaining outer peripheral side portion disposed within the groove 3a. Further, preferably, at least the outermost peripheral portion of the coil 4 is at least partially disposed within the groove 3a. Furthermore, preferably, an outer peripheral side portion of the coil ranging from the second end (winding end) of the outermost peripheral portion to a portion of a length 0.3 L therefrom is at least partially disposed within the groove 3a.

In this case, preferably, the winding density of the coil 4 is made higher at the outer peripheral side portion than the center side portion. That is, when the coil 4 is viewed from the vertical direction with respect to the first surface of the dielectric member 3, preferably, as the coil portion is closer to the center (winding start) of the coil 4, a gap (a distance in a direction in parallel to the surface direction of the dielectric member 3) between the adjacent conductors 4a becomes larger. Further, preferably, as the coil portion is closer to the outer peripheral side, the gap between the adjacent conductors 4a becomes smaller. Consequently, the coupling degree between the coil 4 and the plasma can be made higher at the outer peripheral portion. At a portion near the center, it is possible to suppress occurrence of a phenomenon that the dielectric member 3 and the cover 5 are etched by the plasma and degrade.

The vessel 1, the first holder 17, the second holder 18, and so on, may be formed by metallic material having a sufficient rigidity such as aluminum or stainless steel (SUS). Alternatively, for example, aluminum which surface is subjected to an anodizing treatment may be used. As the dielectric member 3, the cover 5, and so on, may be formed of dielectric material such as yttrium oxide (Y₂O₃), aluminum nitride (AlN), alumina (Al₂O₃) or quartz (SiO₂).

The surface of the dielectric member 3 on the reaction chamber 1a side (i.e., the second surface) may be a flat plane having no irregularity. An electrode layer 19 including a predetermined electrode pattern may be formed on such the flat plane. The electrode pattern can be formed easily on the flat plane. The electrode layer 19 includes, for example, the electrode pattern and an insulation film covering the electrode pattern. The electrode pattern is formed by conductive material. The insulation film may be formed by dielectric material such as ceramics (alumina, for example). The insulation film suppresses generation of metal contamination or particles caused by metal forming the electrode pattern, within the reaction chamber 1a. The insulation film also suppresses damage of the electrode pattern caused by the process gas or the plasma. The electrode layer 19 may be a laminate of plural layers of the electrode pattern and plural layers of the insulation film. The electrode pattern preferably includes, for example, an electric heater for heating the dielectric member 3 and/or a plate electrode 7 for supplying radio frequency power to the dielectric member 3.

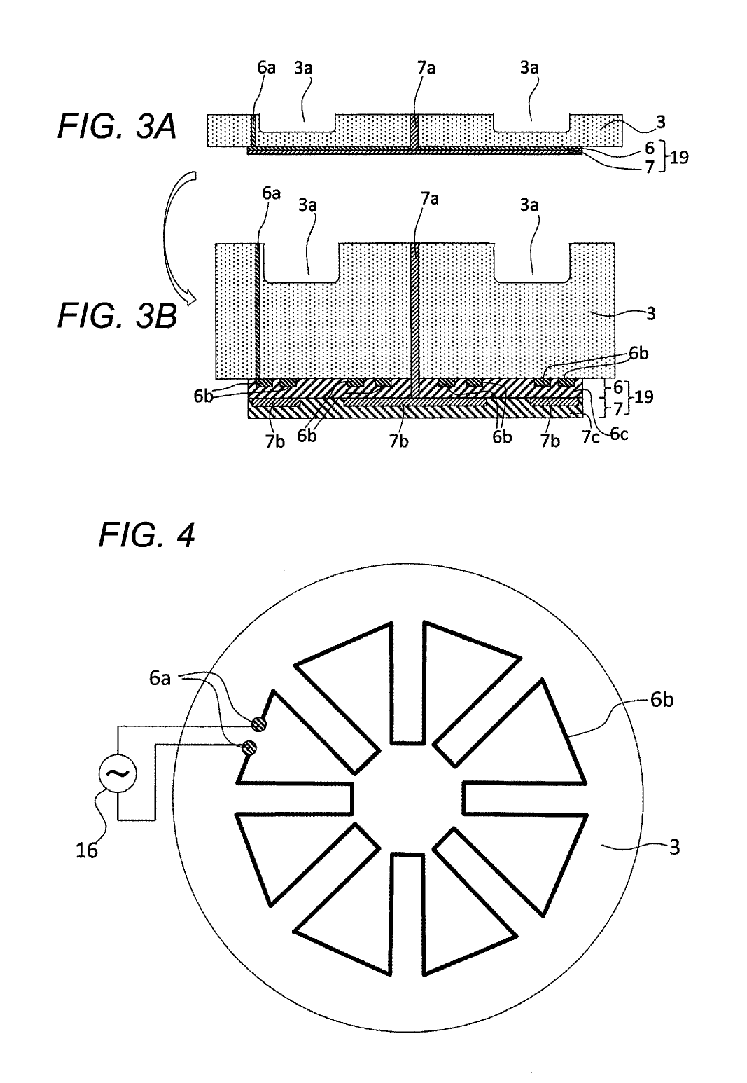

Each of FIGS. 3A and 3B is a longitudinal sectional view schematically showing the configuration of the dielectric member 3 and the electrode layer 19 according to the embodiment. In FIG. 3B, a size of each of the dielectric member 3 and the electrode layer 19 is enlarged in a vertical direction (thickness direction) so as to facilitate understanding.

The electrode layer 19, shown in FIGS. 3A and 3B as an example, may have a multiple-layered structure of a first electrode layer 6 formed on the reaction-chamber 1a side surface of the dielectric member 3 (i.e., the second surface) and a second electrode layer 7 formed on a surface of the first electrode layer 6 on the reaction chamber 1a side. The first electrode layer 6 includes a first electrode pattern 6b formed directly on the second surface of the dielectric member 3 and a first insulation film 6c which covers the first electrode pattern. Similarly, the second electrode layer 7 includes a second electrode pattern 7b and a second insulation film 7c which covers the second electrode pattern. In this manner, the electrode layer 19 having a simple structure can be formed by forming at least one electrode pattern directly on the reaction-chamber 1a side surface of the dielectric member 3.

Hereinafter, an example in which the first electrode pattern 6b is the electric heater and the second electrode pattern 7b is the plate electrode is described.

In order to stabilize processes of a plasma processing, the dielectric member 3 is desirably heated to a predetermined temperature range. For example, temperature of the dielectric member 3 may be managed by providing a plate-shaped hater so as to contact the entire surface of the dielectric member 3 outside the reaction chamber 1a. However, in this case, as the heater is disposed between the dielectric member 3 and the coil 4, a distance between the plasma and the coil 4 becomes large. As a result, a degree of the inductive coupling between the plasma and the coil 4 drops and hence a plasma density reduces. In contrast, in a case of providing the electric heater 6b on the reaction-chamber 1a side surface of the dielectric member 3 (i.e., the second surface), there does not arise a state that a distance between the plasma and the coil 4 becomes large due to the presence of the electric heater 6b. Thus, the processes can be stabilized without reducing the plasma density.

In the plasma processing, suppression of adhesion of non-volatile byproducts to the dielectric member 3 and the cover 5 is also important. Non-volatile material adhered to the dielectric member 3 and the cover 5 may be exfoliated and float within the reaction chamber 1a during a process of the plasma processing. As a result, the object to be processed may be contaminated. The cover 5 suppresses the adhesion of non-volatile material to the dielectric member 3.

The adhesion of non-volatile material to the dielectric member 3 and the cover 5 can be suppressed by forming Faraday shield (FS) in the vicinity of the dielectric member 3 and the cover 5. More specifically, bias voltage is generated between the plasma and each of the dielectric member 3 and the cover 5 by supplying radio frequency power to the plate electrode 7b so as to be capacitively coupled with the plasma. Thus, ions within the plasma acts on the dielectric member 3 and the cover 5 as well as the object to be processed. Accordingly, the adhesion of non-volatile material to the dielectric member 3 and the cover 5 can be suppressed.

According to the aforesaid configuration, as the electric heater 6b can directly heat the dielectric member 3, temperature of the dielectric member 3 can be managed efficiently with a small amount of power. As a distance between the plate electrode 7b and the reaction chamber 1a is short, the bias voltage can be generated even if an amount of power supplied to the plate electrode 7b is small. Further, effect of suppressing the adhesion of non-volatile material to the dielectric member 3 and the cover 5 can be enhanced. The aforesaid configuration is a mere example and may be modified in a manner that the plate electrode is provided directly on the reaction-chamber 1a side surface of the dielectric member 3 as the first electrode pattern, and the electric heater is provided as the second electrode pattern.

FIG. 4 is a plan view showing an example of the electric heater 6b. The electric heater 6b includes a line-shaped pattern formed of high-resistance metal. The line-shaped pattern is drawn in, for example, a serpentine-type shape. The electric heater 6b is connected to heater terminals 6a penetrating the dielectric member 3. The heater terminals 6a are electrically connected to an AC power supply 16. The AC power supply 16 supplies power to the heater terminals 6a to thereby generate heat from the first electrode pattern 6b. For example, tungsten (W) is preferably used as the high-resistance metal.

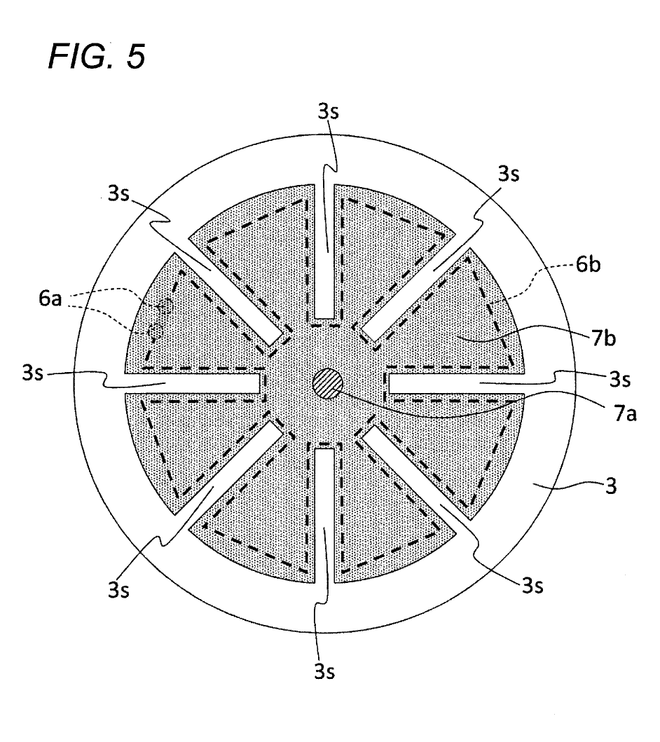

FIG. 5 is a plan view showing an example of the plate electrode 7b. The plate electrode 7b includes a planer pattern formed of a wide metal thin-film. Tungsten (W) can also be used as the plate electrode 7b. The plate electrode 7b is preferably formed to cover, for example, 50% or more of the reaction-chamber 1a side surface of the dielectric member 3 (i.e., the second surface). Consequently, a most part of each of the dielectric member 3 and the cover 5 can be shielded. The plate electrode 7b is provided with a plurality of slits 3s arranged radially in order to transmit radio frequency power outputted from the first radio frequency power supply 11 and the coil 4.

The plate electrode 7b is connected, near the center of the dielectric member 3, to an FS terminal 7a penetrating the dielectric member 3. The FS terminal 7a is electrically connected to a second radio frequency power supply 12. Bias voltage is generated near the second electrode pattern 7b by supplying power to the FS terminal 7a from the second radio frequency power supply 12. Accordingly, the adhesion of non-volatile material to the dielectric member 3 and the cover 5 can be suppressed.

In FIG. 1, although the coil 4 is connected to the first radio frequency power supply 11 and the second electrode layer 7 (plate electrode 7b) is connected to the second radio frequency power supply 12, the coil 4 and the plate electrode 7b may be connected in parallel to the same radio frequency power supply via a variable choke or a variable capacitor. Alternatively, the configuration of FIG. 1 may be modified in a manner that the coil 4 is connected to the first radio frequency power supply 11 and the plate electrode 7b is connected to a variable choke or a variable capacitor, whereby power oscillated from the first radio frequency power supply 11 is superimposed on the plate electrode 7b via air from the coil 4, and a ratio between powers applied to the coil 4 and the plate electrode 7b is adjusted by the variable choke or the variable capacitor.

As shown by a dotted line in FIG. 5, the electric heater 6b is preferably disposed so as not to protrude from an outer periphery of the plate electrode 7b, as viewed from a direction perpendicular to the second surface of the dielectric member 3 (i.e., in plan view). In other words, the electric heater 6b as a whole is disposed within the plate electrode 7b in plan view. Consequently, a loss of radio frequency power transmitting the slits 3s can be suppressed.

Next, an example of a manufacturing method of the electrode layer 19 will be explained.

First, the dielectric member 3 of a disc shape, provided with the groove 3a on the first surface thereof, is prepared. The dielectric member 3 has flat both surfaces in a state not provided with the groove 3a. The dielectric member has a thickness, for example, in a range of 10 to 40 mm at a portion not provided with the groove 3a. The electrode layer 19 is formed on the second surface of the dielectric member 3 in the following manner.

First, a predetermined number of through holes are formed in the dielectric member 3. Conductor is filled or passed in the through holes to form the heater terminals 6a and the FS terminal 7a.

Next, the electric heater 6b is formed on the second surface. The electric heater 6b is formed by spraying high-resistance metal such as tungsten on the second surface via a mask corresponding to the first electrode pattern. A thickness of a sprayed pattern thus formed is, for example, in a range from 10 to 300 μm. Alternatively, the electric heater may be formed in a manner that a tungsten wire is bent into a shape of the first electrode pattern and thereafter the tungsten wire is fixed on the second surface. In this case, the electrode pattern formed by the sprayed pattern or by means of other methods is electrically connected to the heater terminals 6a.

Next, the first insulation film 6c is formed so as to entirely cover the electric heater 6b. White alumina is preferably used as material of the first insulation film 6c. The first insulation film 6c is formed by spraying white alumina on the second surface. In order to enhance adhesiveness between the dielectric member 3 and the first insulation film 6c, before spraying white alumina, an adhesion layer may be formed by spraying yttrium or the like on the second surface. A thickness of the first electrode layer 6 is, for example, in a range from 10 to 300 μm.

Next, the plate electrode 7b is formed on one surface of the first electrode layer 6. The plate electrode 7b is formed by spraying metal on the one surface of the first electrode layer 6 via a mask corresponding to the second electrode pattern. In this case, the plate electrode 7b is formed to have the plurality of slits 3s arranged radially. A thickness of the plate electrode 7b is, for example, in a range from 10 to 300 μm. Alternatively, the plate electrode 7b may be formed in a manner that a plate electrode having a shape of the second electrode pattern is prepared from a metal foil or a metal plate and thereafter this plate electrode is fixed to the one surface of the first electrode layer 6. The plate electrode 7b is disposed so as to completely cover the electric heater 6b via the first insulation film 6c and is electrically connected to the FS terminal 7a.

Next, the second insulation film 7c is formed so as to entirely cover the plate electrode 7b. White alumina is also suitable as material of the second insulation film 7c. The second insulation film 7c is formed by spraying white alumina on the one surface of the first electrode layer 6. A thickness of the second electrode layer 7 is, for example, in a range from 10 to 300 μm. A method of forming each of the first and second insulation films is not limited to the above-described methods but these films may be formed by, for example, sputtering, chemical vapor deposition (CVD), vapor deposition, coating or the like.

An example of operation of the dry etching apparatus 10 according to the embodiment will be explained.

First, atmosphere within the reaction chamber 1a is exhausted. The reaction chamber 1a contains depressurized atmosphere. A pressure almost the same as the atmospheric pressure is applied to the dielectric member 3 is applied. The dielectric member 3 has the groove 3a. A portion of the dielectric member 3 corresponding to the groove 3a has a thin thickness. In this respect, as the groove 3a is formed in the annular shape so that mechanical strength of the dielectric member 3 can be kept to a sufficient degree, the dielectric member 3 is not broken.

Thereafter, process gas is introduced into the reaction chamber 1a via the gas introduction port 8 from the predetermined gas supply source. A substrate 15 to be etched has a resist mask corresponding to an etching pattern. In a case where the substrate 15 is made of, for example, Si, fluorine-based gas (SF₆ or the like), for example, is used as the process gas. In a case where the substrate 15 is made of aluminum, for example, chlorine-based gas (HCl or the like) is used as the process gas.

Next, radio frequency power is supplied to the coil 4 from the first radio frequency power supply 11 to generate plasma within the reaction chamber 1a. At this time, bias voltage is also applied to the lower electrode 2 for holding the substrate 15, from a predetermined radio frequency power supply. Consequently, radicals or ions within the plasma are transported above the surface of the substrate 15, then accelerated by the bias voltage and impinge on the substrate 15. As a result, the substrate 15 is etched.

The outer peripheral side portion with a high winding density of the conductor 4a of the coil 4 is disposed within the annular groove 3a formed in the dielectric member 3. Thus, by supplying a relatively small amount of power to the coil, doughnut-shaped high-density plasma is generated at an area near the dielectric member 3 on the reaction chamber 1a side. The plasma reaches a substrate 15 as diffusion plasma.

Power is supplied from the second radio frequency power supply 12 to the plate electrode 7b which is disposed at the surface side of the dielectric member 3 on the reaction chamber 1a side, thereby generating bias voltage near the plate electrode within the reaction chamber 1a. Thus, a part of ions within the plasma is accelerated by the bias voltage and incident on the dielectric member 3 (or the electrode layer 19) and the cover 5. As a result, adhesion of non-volatile material to the dielectric member 3 (or the electrode layer 19) and the cover 5 can be suppressed.

An etching process is performed continuously to a plurality of substrates 15. Thus, in order to secure stability of this process, power is supplied from the AC supply 16 to the electric heater 6b provided on the reaction-chamber 1a side surface of the dielectric member 3, whereby temperature of the dielectric member 3 is managed by the heating.

### Second Embodiment

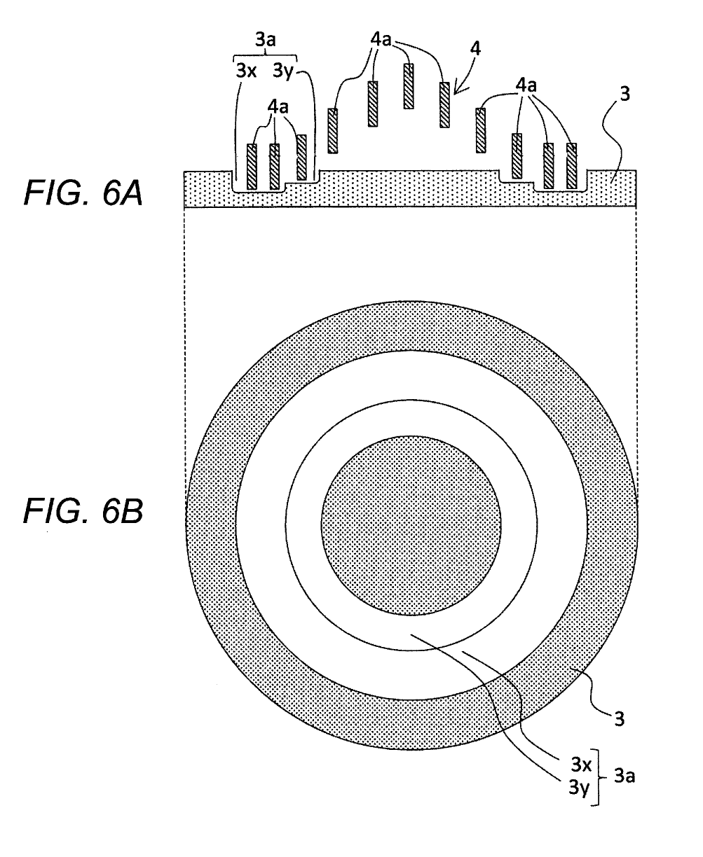

A plasma processing apparatus according to a second embodiment is the same as that of the first embodiment except for a shape of the groove of the dielectric member and a positional relation between the dielectric member and the coil. FIG. 6A is a longitudinal sectional view schematically showing an arrangement of a dielectric member and a coil according to this embodiment. FIG. 6B is a plan view of the dielectric member according to this embodiment. Respective constituent elements of this embodiment corresponding to those of the first embodiment are referred to by the common symbols.

The dielectric member 3 has a circular plate shape. An annular groove 3a is provided in the first surface of the dielectric member 3 such that a center of the annular shape of the groove 3a substantially overlaps with the center of the coil 4 in plan view. The groove 3a includes: a first groove portion 3x having a large depth, formed at an outer-side surface portion of the dielectric member; and a second groove portion 3y having a small depth, formed at an inner-side surface portion of the dielectric member. Consequently, the depth of the groove increases in two steps toward the outer side surface from the center. The coil 4 is partially disposed in both the first groove portion 3x and the second groove portion 3y. In this case, supposing that a width of the groove 3a is the same as that of the first embodiment, an average thickness of the dielectric member 3 in this embodiment is larger than that of the first embodiment. Thus, strength of the dielectric member 3 can be maintained to a larger value.

As the first groove portion 3x of the relatively large depth is disposed at the outer-side surface portion of the dielectric member and the second groove portion 3y of the relatively small depth is disposed at the inner-side surface portion of the dielectric member, a degree of inductive coupling between the coil 4 and the plasma can be increased toward the outer peripheral side of the dielectric member 3. Thus, doughnut-shaped plasma with a higher density can be generated at an area near the dielectric member 3. As a result, uniform diffusion-plasma with a higher density can be reached to a substrate 15. In a case of increasing the depth of the groove 3a toward the outer side surface from the center stepwise, the depth may be changed in three or more steps. Alternatively, the depth of the groove 3a may be increased continuously toward the outer-side surface from the center.

In FIGS. 6A and 6B, an average distance between the dielectric member 3 and the conductor of the coil 4 increases gradually toward the center from the outermost peripheral portion. In this case, the depth of the groove 3a is preferably increased stepwise or continuously toward the outer side surface from the center.

### Third Embodiment

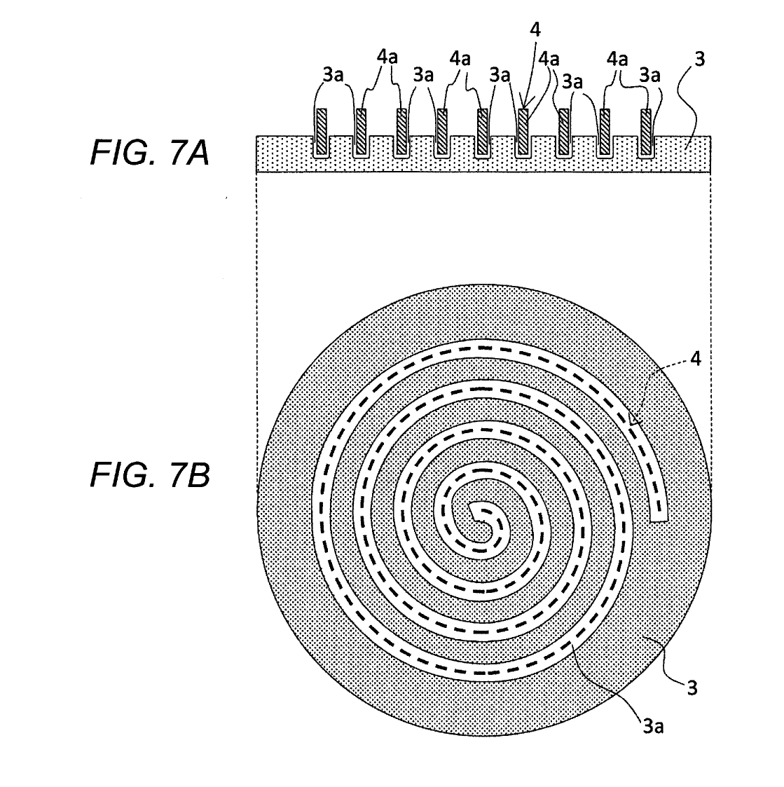

A plasma processing apparatus according to a third embodiment is the same as that of the first embodiment except for a shape of the coil, a shape of the groove of the dielectric member and a positional relation between the dielectric member and the coil. FIG. 7A is a longitudinal sectional view schematically showing an arrangement of a dielectric member and a coil according to this embodiment. FIG. 7B is a plan view of the dielectric member according to this embodiment. In FIGS. 7A and 7B, a position of the coil 4 is shown by a dotted line. Respective constituent elements of this embodiment corresponding to those of the first embodiment are referred to by the common symbols.

The dielectric member 3 has a circular plate shape. A spiral-shaped groove 3a is provided in the first surface of the dielectric member 3 facing the coil 4. The conductor 4a of the coil 4 extends flatly and spirally along the groove 3a, and almost entirety of the coil 4 is disposed in the grove 3a. In a case where the coil 4 has a flat shape in this manner, the groove 3a may be shaped in correspondence with the spiral shape of the conductor 4a. Consequently, a width of the groove 3a can be made small and strength of the dielectric member 3 can be secured more easily.

The plasma processing apparatus according to one or more embodiments of the invention is useful in processes requiring simple maintenance and high-density plasma and can be applied to various types of plasma processing apparatuses such as a dry etching processing apparatus and a plasma CVD apparatus.

What is claimed is:

1. A plasma processing apparatus, comprising:
a vessel which comprises a reaction chamber, atmosphere within the reaction chamber capable of being depressurized;
a lower electrode which supports an object to be processed within the reaction chamber;
a dielectric member which comprises a first surface and a second surface opposite to the first surface, and which closes an opening of the vessel such that the first surface opposes an outside of the reaction chamber and the second surface opposes the object to be processed; and
a coil which opposes the first surface of the dielectric member, and which generates plasma within the reaction chamber,
wherein the dielectric member has a groove formed in the first surface of the dielectric member, and
wherein at least a part of the coil is disposed in the groove.

2. The plasma processing apparatus according to claim 1,
wherein the groove has an annular shape having a center which is substantially overlaps with a center of the coil as viewed from a direction perpendicular to the first surface of the dielectric member.

3. The plasma processing apparatus according to claim 2,
wherein a depth of the groove increases continuously or stepwise toward outside from the center of the annular shape.

4. The plasma processing apparatus according to claim 1,
wherein the coil comprises a conductor having a length L and extending from a first end on a center side to a second end on an outer peripheral side,
wherein the conductor comprises a center side portion having a length 0.5 L extending from the first end and a remaining outer peripheral side portion, and
wherein a ratio of the center side portion disposed within the groove is smaller than a ratio of the remaining outer peripheral side portion disposed within the groove.

5. The plasma processing apparatus according to claim 4,
wherein a winding density of the coil in the first portion is smaller than that of the second potion.

6. The plasma processing apparatus according to claim 1, further comprising:
an electrode pattern and an insulation film which covers the electrode pattern, which are formed on the second surface of the dielectric member.

7. The plasma processing apparatus according to claim 6,
wherein the electrode pattern comprises an electric heater which heats the dielectric member.

8. The plasma processing apparatus according to claim 6,
wherein the electrode pattern comprises a plate electrode which is capacitively coupled to the plasma when the plate electrode is supplied with radio frequency power.

9. The plasma processing apparatus according to claim 1, further comprising:
a first electrode pattern and a first insulation film which covers the first electrode pattern, which are formed on the second surface of the dielectric member,
a second electrode pattern and a second insulation film which covers the second electrode pattern, which are formed on a surface of the first insulation film opposite to the dielectric member,
wherein one of the first and second electrode patterns comprises an electric heater which heats the dielectric member, and
wherein the other of the first and second electrode patterns comprises a plate electrode which is capacitively coupled to the plasma within the reaction chamber when the other of the first and second electrode patterns is supplied with radio frequency power.

10. The plasma processing apparatus according to claim 9,
wherein the electric heater as a whole is disposed within the plate electrode as viewed from a direction perpendicular to the second surface of the dielectric member.
